(19) United States
(12) Patent Application Publication
(10) Pub. No.: US 2002/0173092 A1
(43) Pub. Date: Nov. 21, 2002

(54) Forming devices on a semiconductor substrate

(76) Inventors: Tadanori Yamaguchi, Portland, OR (US); Ken Liao, Beaverton, OR (US); Fanling Yang, Beaverton, OR (US); Robert F. Scheer, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 09/860,932

(22) Filed: May 18, 2001

(51) Int. Cl. H01L 21/8238

(52) U.S. Cl. 438/205; 438/237

(57) ABSTRACT

A method for forming a plurality of devices on a substrate is disclosed. The method includes providing an oxide layer over the substrate, forming diffused regions in the plurality of devices, and performing at least one high-energy implant in the diffused regions. The diffused regions are buried and driven. Oxide layer is then removed. The method also includes depositing an epitaxial layer over the diffused regions, such that the diffused regions are buried under the epitaxial layer, in a single row.

### BACKGROUND

1. Field of the Invention

The present invention relates to an integrated circuit (IC), and more particularly, to formation of devices in such an IC.

2. Prior Art

An integral part of integrated circuits is an epitaxial layer that serves as the collector. The epitaxial layer provides a lightly doped crystalline layer into which subsequent diffusions and implants of dopants may be made during the device fabrication. A buried collector is diffused or implanted into patterned areas of the substrate before the epitaxial layer is formed. For fabrication of NPN transistors, lightly-doped n-type (or intrinsic) epitaxial silicon may be deposited above the heavily doped n-type buried layer.

In order to achieve formation of low-resistance buried collectors, epitaxial deposition processes may deposit thin (<2 μm) film. The deposition should reduce significant diffusion of the dopant, either into the substrate or into the forming epitaxial layer. It is also desirable to minimize loss of the buried layer dopant through evaporation during the epitaxial deposition process and to minimize the re-incorporation of evaporated dopant into the buried layer. Accordingly, the conventional method of forming devices such as NPN transistor, varactor, and/or Schottky diode on a semiconductor substrate often requires formation of at least two epitaxial silicon layer depositions. Moreover, each deposition may be preceded by formation of buried layers. Once this structure is formed, a series of masking and low energy implants may be used to achieve a desired doping profile for each device. However, the process of forming a multiple buried and epitaxial layers, using several different masks, may be time-consuming, cumbersome, and costly.

### SUMMARY

The present invention, in one embodiment, describes a method for forming a plurality of devices on a substrate. The method includes providing an oxide layer over the substrate, forming diffused regions in the plurality of devices, and performing at least one high-energy implant in the diffused regions. The diffused regions are buried and driven. Oxide layer is then removed. The method also includes depositing an epitaxial layer over the diffused regions, such that the diffused regions are buried under the epitaxial layer, in a single row.

An alternative method includes providing a first oxide layer over the substrate, forming a first set of diffused regions under a first selected combination of the plurality of devices, and performing a first set of at least one high-energy implant in the first set of diffused regions. The first oxide layer is then removed. The method also includes providing a second oxide layer over the substrate, forming a second set of diffused regions under a second selected combination of the plurality of devices, and performing a second set of at least one high-energy implant in said second set of diffused regions. The method further includes burying and driving the diffused regions, and removing the second oxide layer. An epitaxial layer is then deposited over the diffused regions, such that the diffused regions of the plurality of devices are buried under the epitaxial layer.

### BRIEF DESCRIPTION OF THE DRAWINGS

FIGS. 1A through 1F illustrate a conventional technique for forming devices on the semiconductor substrate.

FIGS. 2A through 2C illustrate a technique for forming devices on a semiconductor substrate according to an embodiment of the present invention.

FIGS. 3A through 3C illustrate an alternative embodiment of the technique for forming devices on a semiconductor substrate.

### DETAILED DESCRIPTION

In recognition of the above-described difficulties in forming multiple epitaxial and buried layers, the present invention describes a technique for forming devices on a semiconductor substrate. The technique uses a single buried layer formation and epitaxial layer deposition. Each component is then masked, and at least one high-energy implant may be performed to achieve a desired doping profile. Consequently for purposes of illustration and not for purposes of limitation, the exemplary embodiments of the invention are described in a manner consistent with such use, though clearly the invention is not so limited.

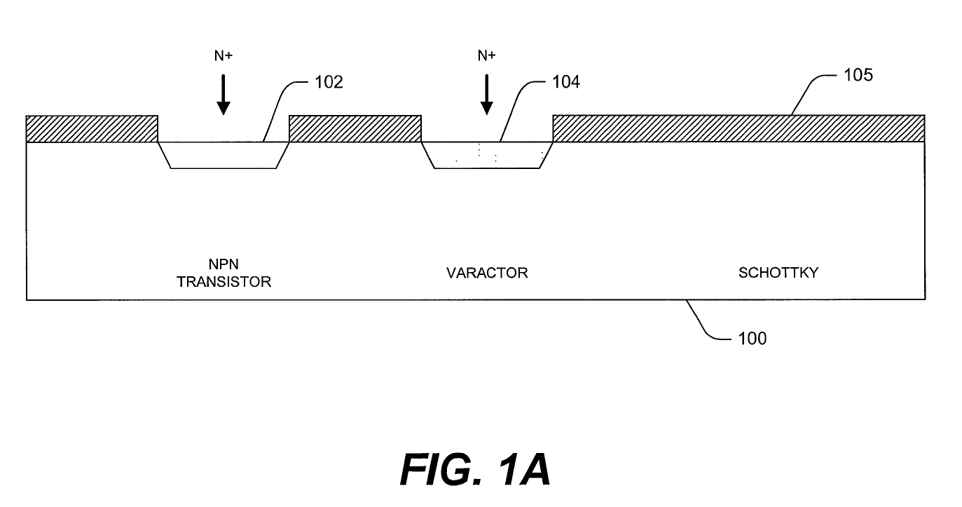

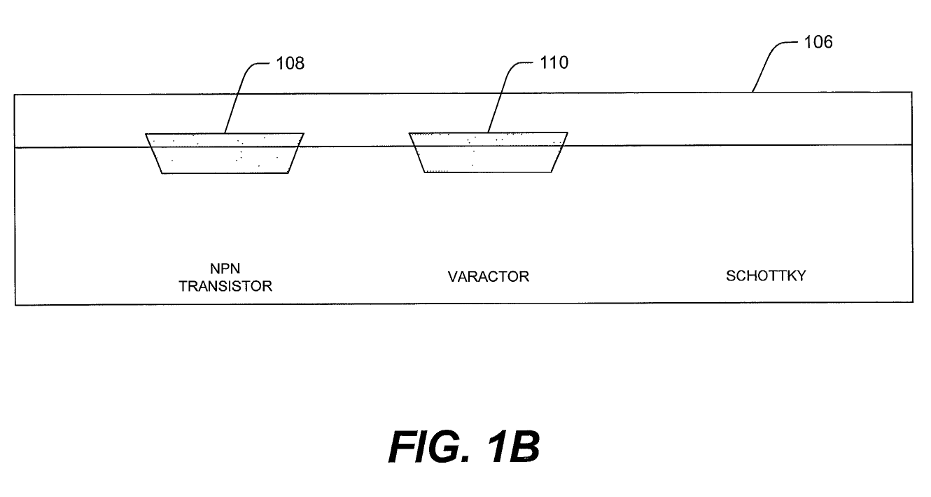

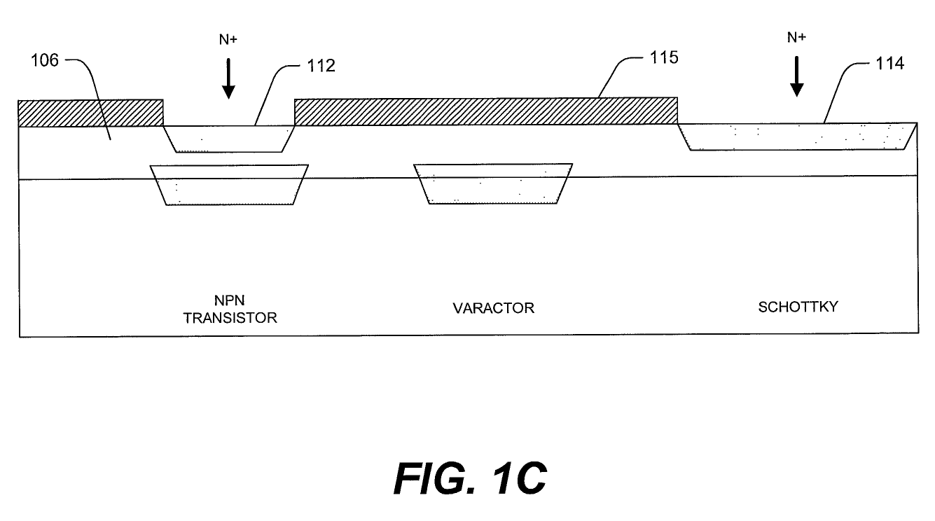

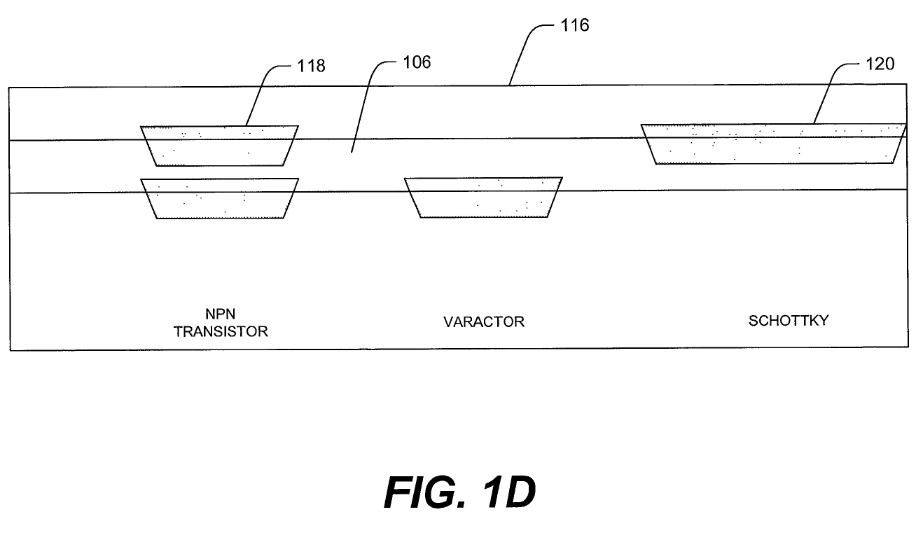

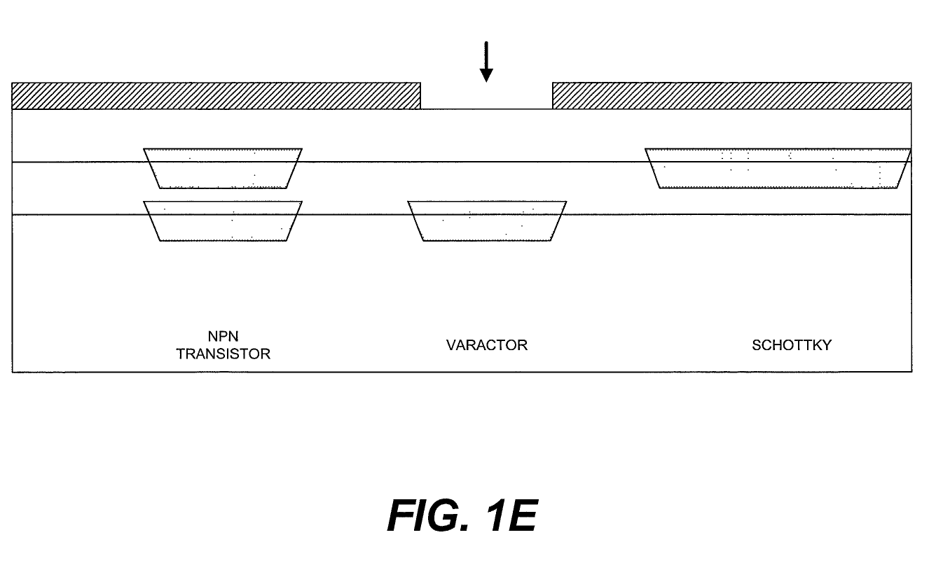

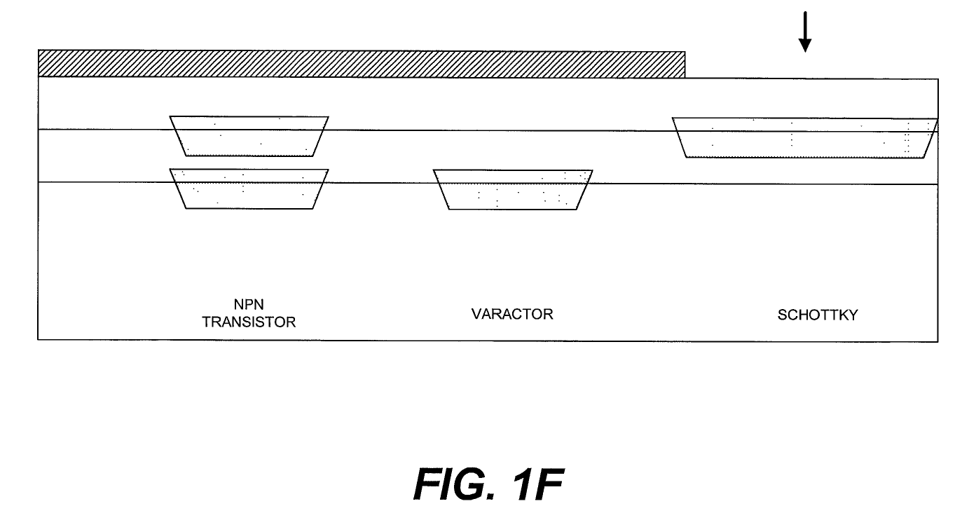

FIGS. 1A through 1F illustrate a conventional technique for forming devices on the semiconductor substrate. The technique shows that at least two epitaxial layers are needed to form a combination of devices such as NPN transistors, varactors, and Schottky diodes.

In the illustrated embodiment of FIG. 1A, the technique includes providing a p-type wafer substrate 100 into which n-type diffusions may be made. However, the types of substrate and diffusions may be varied according to a particular need. The oxidation and masking required to create the diffused regions 102, 104 have been omitted for brevity. In the illustrated example, the devices to be formed on the substrate 100 include NPN transistor, varactor, and Schottky diode.

In FIG. 1A, two n-type diffused regions 102, 104 are made for the NPN transistor and varactor, respectively. The diffused regions 102, 104 may be formed by using a silicon dioxide layer 105 as a diffusion mask.

After the diffused regions 102, 104 are formed, an epitaxial layer 106 may be deposited as shown in FIG. 1B. The epitaxial layer 106 in FIG. 1B may be of n-type. As mentioned above, the epitaxial layer 106 serves as the collector. This leaves the diffused regions 102, 104 buried under the epitaxial layer 106. The buried diffused regions are referred to as buried layers 108, 110 (or sub-collectors) of the transistor. One of the functions of the buried layers 108, 110 is to provide a lower-resistance path for the collector current as it flows out of the base region on its way to the surface collector contact.

FIG. 1C shows a second layer of diffused regions 112, 114 that may be deposited over the NPN transistor and Schottky diode, respectively. In the illustrated example, the diffused regions 112, 114 are made in the first epitaxial layer 106. Again, the oxidation and masking required to create the diffused regions 112, 114 have been omitted for brevity. The diffused regions 112, 114 may be formed by using a silicon dioxide layer 115 as a diffusion mask.

After the second set of diffused regions 112, 114 are formed, a second epitaxial layer 116 may be deposited as shown in FIG. 1D. Again, the second epitaxial layer 116 may be of n-type. This leaves the diffused regions 112, 114 buried under the epitaxial layer 116. The diffused regions 112, 114 correspond to buried layers 118, 120, respectively. Additional masking and low-energy implants may be performed to control the varactor and Schottky diode doping profiles as shown in FIGS. 1E and 1F, respectively.

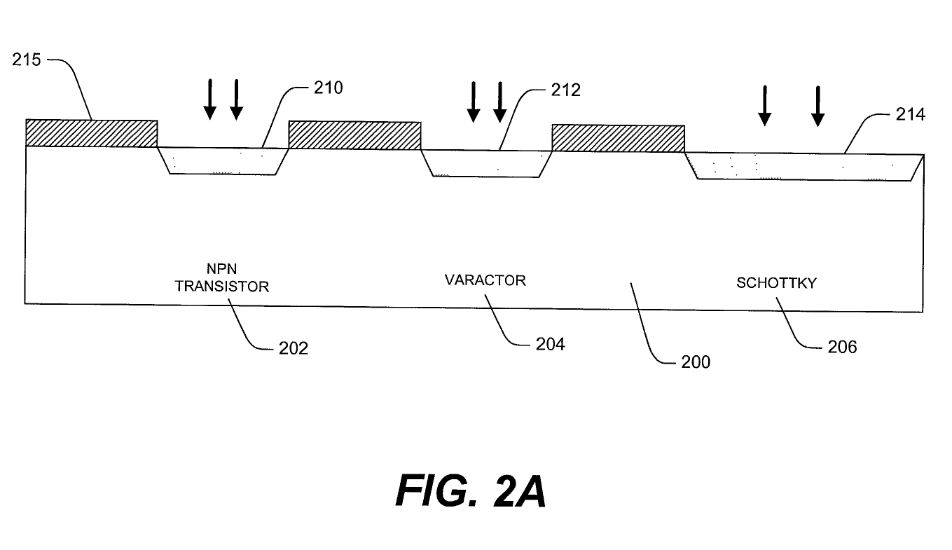

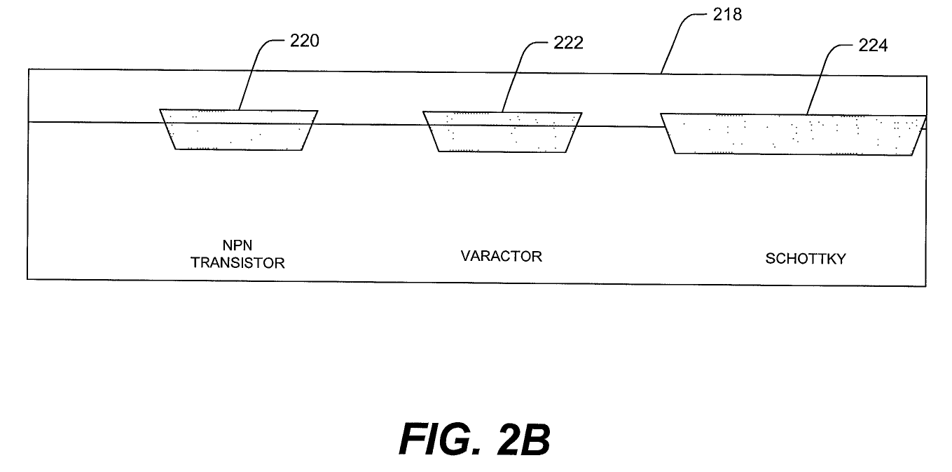

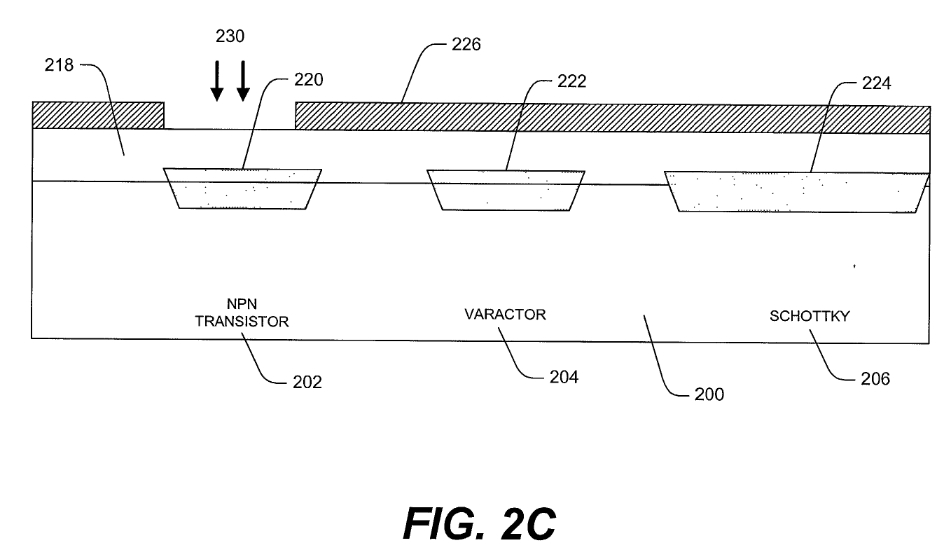

As already mentioned, the process of forming a multiple buried and epitaxial layers may be time-consuming, cumbersome, and costly. Consequently, FIGS. 2A through 2C illustrate a technique for forming devices on a semiconductor substrate 200 according to an embodiment of the present invention. The technique involves using a single buried layer formation and epitaxial layer deposition, followed by at least one high-energy implant.

In the illustrated example of FIG. 2A, the devices to be formed on the substrate 100 include NPN transistor, varactor, and/or Schottky diode. However, different combinations of the above-mentioned devices or other devices may be formed using a similar technique as described below. The technique includes providing a wafer substrate 200 into which diffused regions 210, 212, 214 may be formed. The oxidation and masking required to create the diffused regions 210, 212, 214 have been omitted from the illustration for brevity and clarity. The diffused regions 210, 212, 214 may be formed by using a silicon dioxide layer 215 as a diffusion mask. In the illustrated embodiment, three diffused regions 210, 212, 214 are made for the NPN transistor, varactor, and Schottky diode, respectively. Thus, all three diffused regions 210, 212, 214 are formed on the substrate 200.

After the diffused regions 210, 212, 214 are formed, resist is removed and cleaned. Moreover, the regions 210, 212, 214 are buried and driven. Further, an epitaxial layer 218 may be deposited as shown in FIG. 2B. The epitaxial layer 218 may include a silicon film having a thickness less than 2 μm. As mentioned above, the epitaxial layer 218 may serve as the collector. This leaves the diffused regions 210, 212, 214 buried under the epitaxial layer 218, in a single row. The diffused regions 210, 212, 214 correspond to buried layers 220, 222, 224, respectively.

FIG. 2C shows oxidation and masking of the NPN transistor 202 using a silicon dioxide layer 226 as a mask. This may be followed by at least one high-energy implant 230 over the epitaxial layer 218, which act as the collector of the transistor 202. Thus, “at least one high-energy implant” 230 may be a single implant or a series of implants. The epitaxial layer 218 may then be doped to form base and emitter regions (not shown) of the transistor 202. Further, metal contacts (not shown) may be deposited on top of the epitaxial layer 218. Accordingly, the high-energy implants 230 may provide a link between the buried layer (sub-collector) 220 and the base of the transistor 202.

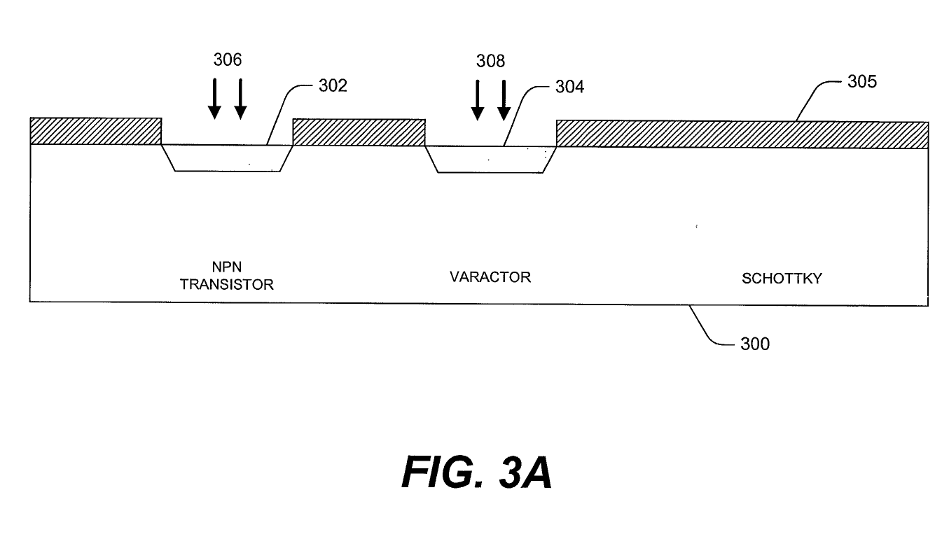

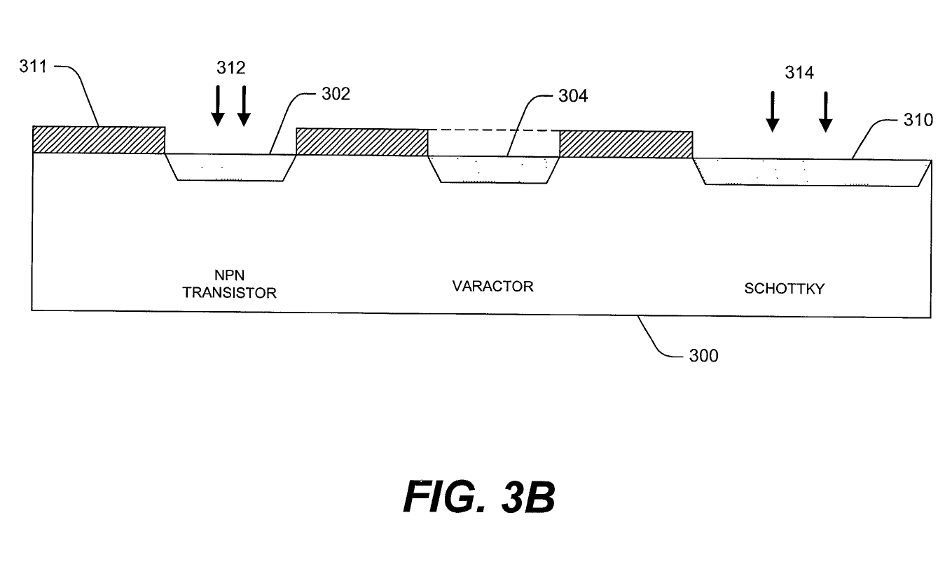

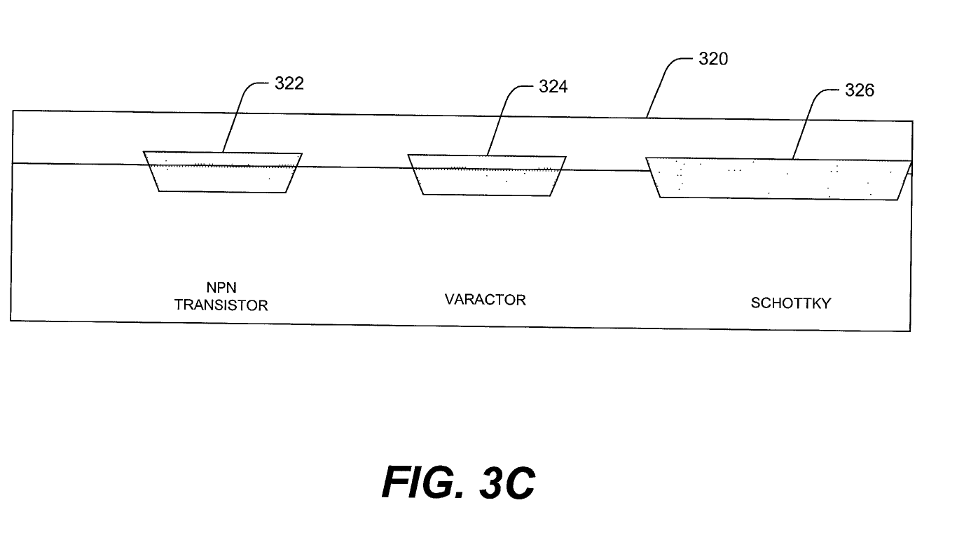

An alternative embodiment of the present invention may be seen in FIGS. 3A through 3C. This embodiment is substantially similar to the embodiment shown in FIGS. 2A through 2C. However in the alternative embodiment, the application of high-energy implants are performed prior to the deposition of an epitaxial layer. Further, the alternative embodiment is different than the conventional method. Although the formation of the NPN-varactor and NPN-Schottky diode diffused regions followed by a series of high-energy implants are performed sequentially, the embodiment uses a single buried layer formation and epitaxial layer deposition.

The alternate technique, shown in FIG. 3A, includes providing a wafer substrate 300 into which diffused regions 302, 304 may be formed. The oxidation and masking required to create the diffused regions 302, 304 have been omitted from the illustration for brevity and clarity. As seen in FIG. 3A, the diffused regions 302, 304 may be formed by using a silicon dioxide layer 305 as a diffusion mask. In the alternative embodiment, only two diffused regions 302, 304 are made for the NPN transistor and varactor, respectively. The diffused regions 302, 304 are formed on the substrate 300. At least one high-energy implant 306, 308 may be performed over the diffused regions 302, 304 to control the NPN transistor and varactor doping profiles.

After the diffused regions 302, 304 are formed, resist and oxide layer 305 are removed and cleaned. A new oxide layer 311 is grown over the substrate 300 (see FIG. 3B). Diffused regions 302, 310 may undergo high-energy implants 312, 314 performed over the NPN transistor and Schottky diode. The oxide layer 311 over the diffused region 304 may be etched and cleaned before or after the high-energy implants 312, 314, to prepare the region 304. The diffused regions 302, 304, 310 are then buried and driven, as shown in FIG. 3C, to form buried layers 322, 324, 326. An epitaxial layer 320 may be deposited as shown.

There has been disclosed herein a method for forming devices in a semiconductor substrate. The method may select different combinations of diffused region formations and high-energy implants to form a single buried layer formation and epitaxial layer deposition. This method provides advantages that include relatively fast and simplified device fabrication process and lower manufacturing cost. While specific embodiments of the invention have been illustrated and described, such descriptions have been for purposes of illustration only and not by way of limitation. Accordingly, while these embodiments have been disclosed in detail herein, it will be understood by those skilled in the art that various changes in form and detail may be made therein without departing from the spirit and scope of the invention as defined by the following claims, giving the full scope thereto.

What is claimed is:

1. A method for forming a plurality of devices on a substrate, comprising:
providing a first oxide layer over the substrate;
forming diffused regions in the plurality of devices;
performing a first at least one high-energy implant in said diffused regions;
burying and driving said diffused regions, and removing said first oxide layer; and
depositing an epitaxial layer over said diffused regions, such that said diffused regions of the plurality of devices are buried under said epitaxial layer, in a single row.

2. The method of claim 1, wherein said plurality of devices includes an NPN transistor.

3. The method of claim 2, wherein said substrate is of p-type.

4. The method of claim 3, wherein said diffused regions are of n-type.

5. The method of claim 4, wherein said epitaxial layer is of n-type.

6. The method of claim 2, wherein said plurality of devices includes a varactor.

7. The method of claim 6, wherein said plurality of devices includes a Schottky diode.

8. The method of claim 1, further comprising:
selectively providing a second oxide layer over the epitaxial layer; and
performing a second at least one high-energy implant over selected diffused regions.

9. The method of claim 8, wherein said selected diffused regions include at least one diffused region in said plurality of devices.

10. The method of claim 1, further comprising:
depositing resist over the first oxide layer.

11. The method of claim 10, further comprising:
exposing the resist and etching the first oxide layer over the plurality of devices.

12. The method of claim 11, further comprising:
removing and cleaning the resist.

13. The method of claim 1, wherein said burying and driving transforms said diffused regions in the plurality of devices into a plurality of buried areas within said epitaxial layer.

14. The method of claim 1, wherein the epitaxial layer includes silicon film having a thickness less than 2 μm.

15. A method for forming a plurality of devices on a substrate, comprising:
first providing a first oxide layer over the substrate;
first forming a first set of diffused regions under a first selected combination of the plurality of devices;
first performing a first at least one high-energy implant in said first set of diffused regions;
removing said first oxide layer;
second providing a second oxide layer over the substrate;
second forming a second set of diffused regions, in conjunction with the first set of diffused regions, under a second selected combination of the plurality of devices;
second performing a second at least one high-energy implant in said second set of diffused regions;
burying and driving said diffused regions, and removing said second oxide layer; and
depositing an epitaxial layer over said diffused regions, such that said diffused regions of the plurality of devices are buried under said epitaxial layer.

16. The method of claim 15, wherein said second performing includes performing the second at least one high-energy implant in selected regions of said first sets of diffused regions.

17. A method for forming a plurality of devices on a substrate, comprising:
providing a first oxide layer over the substrate;
depositing resist over the first oxide layer;
exposing the resist and etching the first oxide layer over the plurality of devices;
removing and cleaning the resist;
forming diffused regions in the plurality of devices;
performing at least one high-energy implant in said diffused regions;
burying and driving said diffused regions, and removing said first oxide layer;
depositing an epitaxial layer over said diffused regions, such that said diffused regions of the plurality of devices are buried under said epitaxial layer;
selectively providing a second oxide layer over the epitaxial layer; and
performing a second at least one high-energy implant over selected diffused regions.
